(19) United States
(12) Patent Application Publication
(10) Pub. No.: US 2008/0153302 A1
(43) Pub. Date: Jun. 26, 2008

(54) Forming heaters for phase change memories

(76) Inventor: John M. Peters, Cupertino, CA (US)

Correspondence Address: TROP PRUNER & HU, PC, 1616 S. VOSS ROAD, SUITE 750, HOUSTON, TX, 77057-2631, US

(21) Appl. No.: 12/074,813

(22) Filed: Mar. 6, 2008

Related U.S. Application Data
(62) Division of application No. 11/248,488, filed on Oct. 12, 2005.

(51) Int. Cl. H01L 21/311

(52) U.S. Cl. 438/703; 257/E21.249

(57) ABSTRACT

Rather than depositing a heater material into a pore, a heater material may be first blanket deposited. The heater material may then be covered by a mask, such that the mask and the heater material may be etched to form a stack. Then, the region between adjacent stacks that form separate cells may be filled with an insulator. After removing the mask material, a pore is then formed in the insulator over the heater. This may then be filled with chalcogenide to form a phase change memory.

### CROSS-REFERENCE TO RELATED APPLICATION

This is a divisional of co-pending U.S. Ser. No. 11/248,488, filed Oct. 12, 2005, which is hereby incorporated by reference.

### BACKGROUND

This invention relates generally to phase change memories.

Phase change memory devices use phase change materials, i.e., materials that may be electrically switched between a generally amorphous and a generally crystalline state, for electronic memory application. One type of memory element utilizes a phase change material that may be, in one application, electrically switched between a structural state of generally amorphous and generally crystalline local order or between different detectable states of local order across the entire spectrum between completely amorphous and completely crystalline states. The state of the phase change materials is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

### BRIEF DESCRIPTION OF THE DRAWINGS

FIG. 1 is an enlarged, cross-sectional view at an early stage of manufacture in the row direction in accordance with one embodiment;

FIG. 2 is an enlarged, cross-sectional view corresponding to FIG. 1 in the column direction in accordance with one embodiment;

FIG. 3 is an enlarged, cross-sectional view at a stage subsequent to that shown in FIG. 1 in accordance with one embodiment;

FIG. 4 is an enlarged, cross-sectional view at a stage subsequent to that shown in FIG. 2 in accordance with one embodiment;

FIG. 5 is an enlarged, cross-sectional view at a stage subsequent to that shown in FIG. 3 in accordance with one embodiment;

FIG. 6 is an enlarged, cross-sectional view at a stage subsequent to that shown in FIG. 4 in accordance with one embodiment;

FIG. 7 is an enlarged, cross-sectional view at a stage subsequent to that shown in FIG. 5 in accordance with one embodiment;

FIG. 8 is an enlarged, cross-sectional view at a stage subsequent to that shown in FIG. 6 in accordance with one embodiment;

FIG. 9 is an enlarged, cross-sectional view at a stage subsequent to that shown in FIG. 7 in accordance with one embodiment;

FIG. 10 is an enlarged, cross-sectional view at a stage subsequent to that shown in FIG. 8 in accordance with one embodiment;

FIG. 11 is an enlarged, cross-sectional view at a stage subsequent to that shown in FIG. 9 in accordance with one embodiment;

FIG. 12 is an enlarged, cross-sectional view at a stage subsequent to that shown in FIG. 10 in accordance with one embodiment;

FIG. 13 is an enlarged, cross-sectional view at a stage subsequent to that shown in FIG. 11 in accordance with one embodiment;

FIG. 14 is an enlarged, cross-sectional view at a stage subsequent to that shown in FIG. 12 in accordance with one embodiment;

FIG. 15 is an enlarged, cross-sectional view at a stage subsequent to that shown in FIG. 13 in accordance with one embodiment;

FIG. 16 is an enlarged, cross-sectional view at a stage subsequent to that shown in FIG. 14 in accordance with one embodiment; and

FIG. 17 is a system depiction of one embodiment of the present invention.

### DETAILED DESCRIPTION

In accordance with some embodiments of the present invention, a heater for a phase change memory may be formed without using pore deposition processes. A pore deposition process is a process wherein the heater material is deposited into a pore. Such a deposition process has many problems. One problem is the creation of keyholing or voids within the deposited heater material. Another problem is that the height of the heater is set by a dry or wet etch back and, thus, may be hard to control.

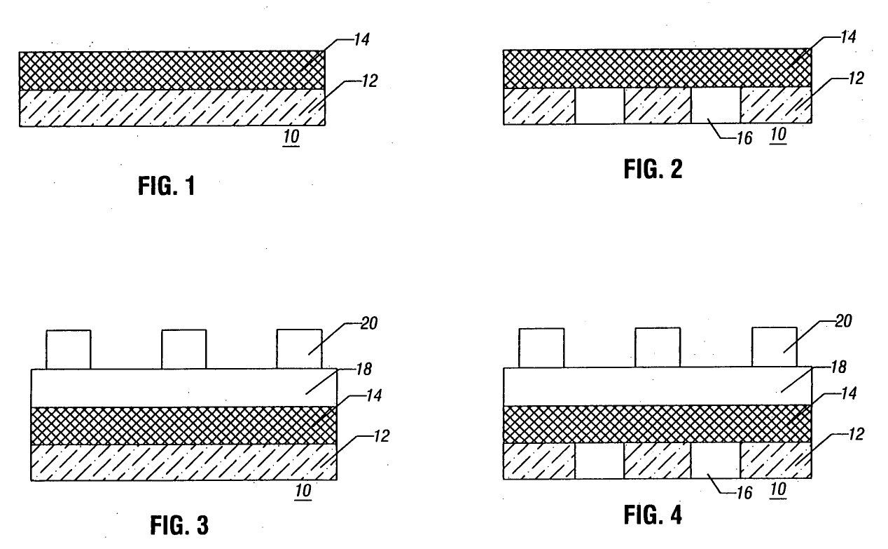

Referring to FIG. 1, at an early stage, a row metal 12 may be formed over a substrate 10. The substrate 10 may, for example, be an interlayer dielectric or even a semiconductor substrate. While the layer 12 is referred to as a row metal, this is simply a convention and it equally well could be considered a column in some embodiments. In some embodiments, over the row metal 12 may be formed the heater 14. The heater 14 may be blanket deposited. For example, the heater 14 may be titanium silicon nitride in one embodiment. The same structure is shown in FIG. 2, but taken in the direction of what ultimately will be the column that extends transversely to the row metal 12. Thus, the row metal 12 is elongate and adjacent row metals 12 are separated by insulating layers 16.

Referring to FIG. 3, which, again, is in the row direction as was the case in FIG. 1, a hard mask 18 is formed over the heater 14. The hard mask 18, in one embodiment, may be silicon nitride. In general, it is desirable that the hard mask 18 be formed of a material which is selectively etchable relative to the surrounding materials including the underlying heater 14, for reasons which will be more apparent subsequently. Over the hard mask 18 may be formed patterned photoresist 20. The same structure appears in FIG. 4, taken in the column direction.

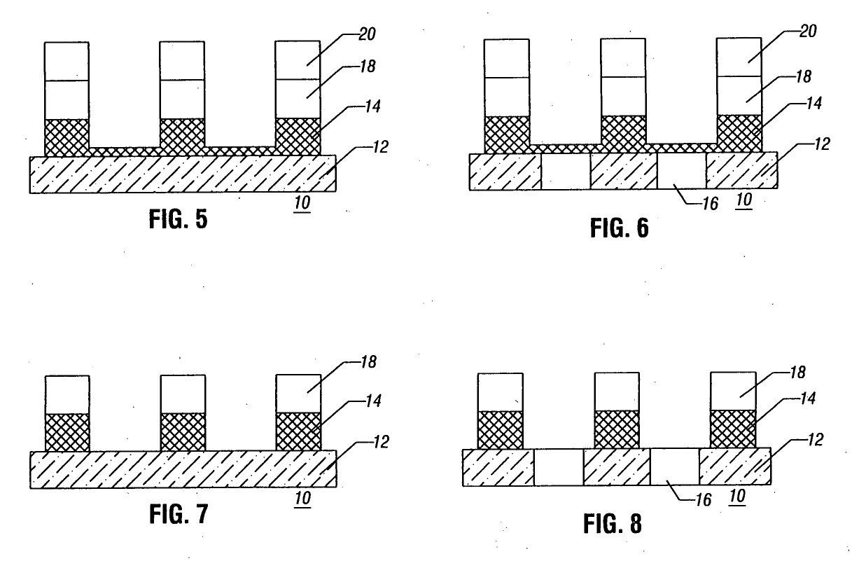

Referring to FIG. 5, the patterned photoresist 20 is then used as an etch mask to etch the hard mask 18 and to partially etch the heater 14 in one embodiment. The heater 14 is only partially etched so that the photoresist 20 can be removed before the row metal 12 is exposed. Otherwise, copper corrosion could occur during the resist ash. The corresponding structure in the column direction is shown in FIG. 6.

Then, referring to FIG. 7, after removing the photoresist 20 using a resist ash, the etching of the heater 14 can be completed down to the row metal 12. The corresponding structure in the column direction is shown in FIG. 8.

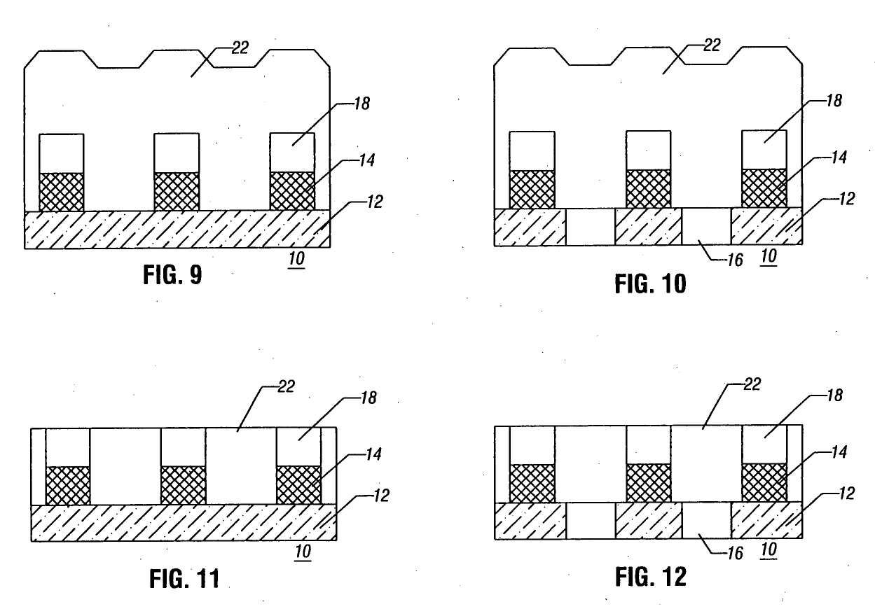

Referring next to FIGS. 9 and 10, an insulator 22 may be blanket deposited over the entire structure. In some embodiments, the insulator 22 may be high density plasma (HDP) oxide fill. As shown in FIGS. 11 and 12, the structure of FIGS. 9 and 10 may be planarized down to the hard mask 18.

Then, it is desirable to remove the remaining portions of the hard mask 18. This may be done using a wet etch, such as a hot phosphoric acid etch at 70° C., that attacks the hard mask 18 at a much faster rate than the insulator 22 or the heater 14. In other words, the etch is selective to the hard mask 18 versus the surrounding materials, namely, the insulator 22 and the heater 14. Where the insulator 22 is HDP oxide and the heater 18 is titanium silicon nitride, hot phosphoric acid at 70° C. may be effective. In other embodiments, a dry etch that selectively etches the hard mask at a faster rate than the insulator 22 or heater 14 may be used.

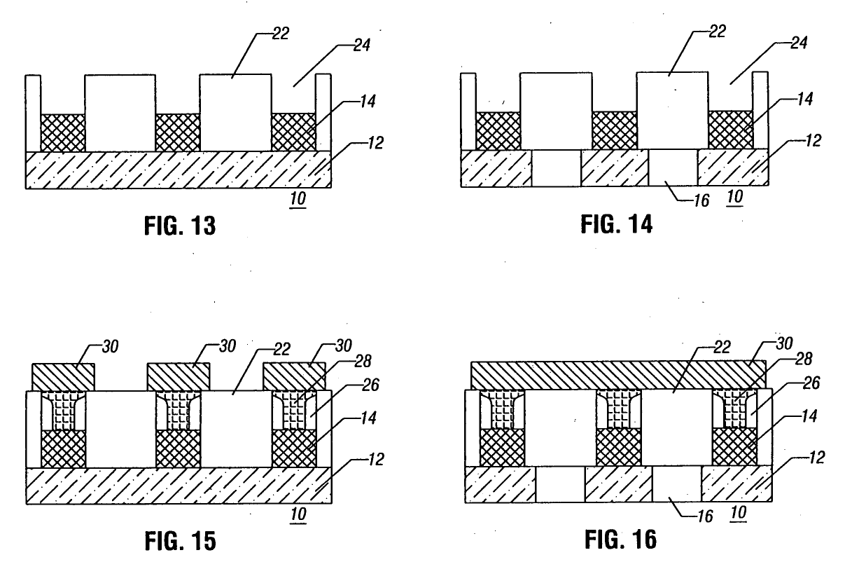

A self-aligned process may be implemented. In other words, because of the selectivity of the etch, the material that is removed corresponds precisely to that of the hard mask 18, leaving a pore 24, as shown in FIGS. 13 and 14, nicely aligned above the heater 14.

The heater 14 may be free of keyholing because it was blanket deposited. Moreover, the height of the heater 14 is set by deposition (rather than by an etch back process) and is, therefore, inherently controllable. The depth of the pore 24 is set both by the thickness of the hard mask 18 and the ability of the planarization step to stop on the end point on the top surface.

In some embodiments, as shown in FIGS. 15 and 16, a sidewall spacer 26 may be deposited and anisotropically etched to reduce the pore's critical dimension. Then, the remaining pore 24 may be filled with a chalcogenide material 28 which is thereafter planarized to align with the top surface of the insulator 22. An upper electrode 30 may be deposited, patterned, and etched. The upper electrode 30 extends generally transversely to the row metal 12. It too may be formed of copper in some embodiments. In some embodiments, it may be desirable to provide a copper barrier layer (not shown) which separates the column electrode 30 from the rest of the structure.

In accordance with another embodiment of the present invention, the hard mask 18 may be implemented by a thermally decomposable material. Namely, a material which thermally decomposes at a temperature higher than the deposition temperature of the insulator 22 may be used instead of selective etching. Upon the application of heat of a suitable temperature, the material vaporizes or thermally decomposes, creating the gap corresponding to the pore 24 shown in FIG. 13. A variety of polymer materials may have suitable decomposition temperatures including polynorbornene, as one example. Other materials which are used in sacrificial applications may be used as well, including those that may be removed by exposure to various environmental circumstances including radiation exposure, chemical exposure, or heat, to mention a few examples.

In accordance with another embodiment of the present invention, the hard mask 18 may be constructed as a two layer construction. The first layer may be a relatively thin nitride, covered by a thicker material such as an oxide or SiON, as two examples. The thin nitride may act as a stopping layer during the etch shown in FIG. 5. This avoids any exposure of the heater 14 during the resist strip in an oxidizing ambient. Moreover, the nitride lower layer may also reduce the possibility of oxidation of the heater during any oxide hard mask deposition. After stripping the resist, the process would continue as before, etching the residual nitride and then the heater 14. Use of a nitride/oxide stack may assist the etch because usually the heater is very similar to nitride.

Programming of the chalcogenide material 28 to alter the state or phase of the material may be accomplished by applying voltage potentials to the lower electrode 12 and upper electrode 30, thereby generating a voltage potential across the select device and memory element. When the voltage potential is greater than the threshold voltages of select device and memory element, then an electrical current may flow through the chalcogenide material 28 in response to the applied voltage potentials, and may result in heating of the chalcogenide material 28.

This heating may alter the memory state or phase of the chalcogenide material 28. Altering the phase or state of the chalcogenide material 28 may alter the electrical characteristic of memory material, e.g., the resistance of the material may be altered by altering the phase of the memory material. Memory material may also be referred to as a programmable resistive material.

In the “reset” state, memory material may be in an amorphous or semi-amorphous state and in the “set” state, memory material may be in an a crystalline or semi-crystalline state. The resistance of memory material in the amorphous or semi-amorphous state may be greater than the resistance of memory material in the crystalline or semi-crystalline state. It is to be appreciated that the association of reset and set with amorphous and crystalline states, respectively, is a convention and that at least an opposite convention may be adopted.

Using electrical current, memory material may be heated to a relatively higher temperature to amorphosize memory material and “reset” memory material (e.g., program memory material to a logic “0” value). Heating the volume of memory material to a relatively lower crystallization temperature may crystallize memory material and “set” memory material (e.g., program memory material to a logic “1” value). Various resistances of memory material may be achieved to store information by varying the amount of current flow and duration through the volume of memory material.

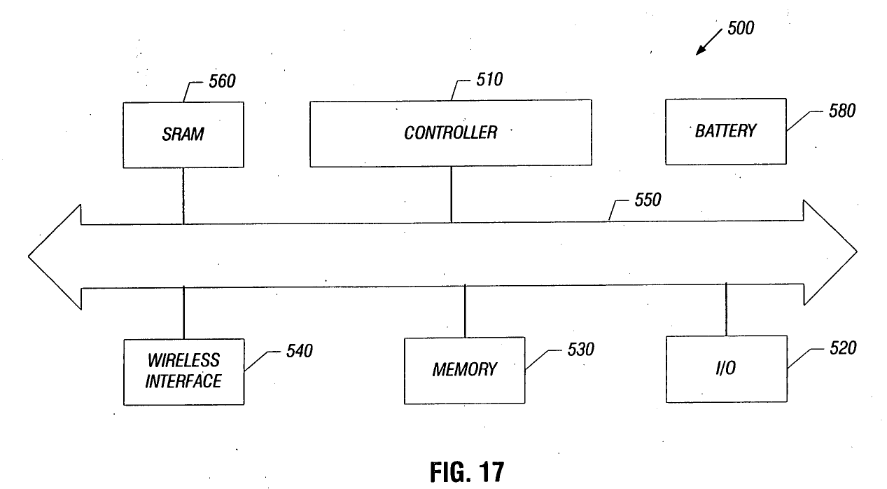

Turning to FIG. 17, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), static random access memory (SRAM) 560, a memory 530, and a wireless interface 540 coupled to each other via a bus 550. A battery 580 may be used in some embodiments. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a memory such as memory discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
blanket depositing a planar layer to form a heater;
patterning a mask over the planar layer;
etching to define a stack including said mask and layer by partially etching through said layer but stopping before completing the etch through said layer;
covering the stack with an insulator; and
removing the mask to define a pore.

2. The method of claim 1 wherein removing the mask to define a pore includes etching the mask to define a pore.

3. The method of claim 2 including selectively etching the mask to define a pore.

4. The method of claim 3 including using an etchant which selectively removes the mask relative to the insulator.

5. The method of claim 1 including using photoresist as a mask to etch to define said stack.

6. The method of claim 5 including depositing said planar layer over a copper conductive line and removing said photoresist before exposing said copper conductive line.

7. The method of claim 3 including providing a sidewall spacer in said pore.

8. The method of claim 1 including filling said pore with a chalcogenide.
